(19) United States
(12) Patent Application Publication
(10) Pub. No.: US 2014/0332048 A1
(43) Pub. Date: Nov. 13, 2014

(54) THERMOELECTRIC DEVICE

(71) Applicant: VERN GREEN POWER SOLUTIONS, LLC, Farmington Hills, MI (US)

(72) Inventors: Emmanuel P Gauzer, Farmington Hills, MI (US); Yury Vernikovskiy, Moscow (RU)

(21) Appl. No.: 14/272,732

(22) Filed: May 8, 2014

Related U.S. Application Data
(60) Provisional application No. 61/927,268, filed on Jan. 14, 2014.
(60) Provisional application No. 61/845,249, filed on Jul. 11, 2013.
(60) Provisional application No. 61/820,765, filed on May 8, 2013.

(51) Int. Cl. H01L 35/30

(52) U.S. Cl. CPC H01L 35/30
USPC 136/205

(57) ABSTRACT

A thermoelectric device includes at least one first heat exchange member. The first heat exchange member includes a conductive body having top and bottom surfaces joined by side surfaces. The top and bottom surfaces include a thin film of active material deposited thereon. The active material includes one of P-type and N-type thermoelectric materials positioned oppositely on the top and bottom surfaces. The thin film of active material includes an anti-diffusion coating deposited thereon. The anti-diffusion coating includes a joining layer deposited thereon. The conductive body of the first heat exchange member includes heat transfer passages formed therein receiving a heat transfer liquid. At least one second heat exchange member includes a conductive body having top and bottom surfaces joined by side surfaces. The top and bottom surfaces including a joining layer deposited thereon. The conductive body of the second member includes heat transfer surfaces formed therein receiving a heat transfer medium. The first and second heat exchange members are connected to each other at the joining layer and a temperature differential is created between the first and second heat exchange members.

### CROSS-REFERENCE TO RELATED APPLICATIONS

This application claims priority of U.S. Provisional Patent Application Ser. No. 61/820,765 filed May 8, 2013 and U.S. Provisional Patent Application Ser. No. 61/845,249 filed Jul. 11, 2013 and U.S. Provisional Patent Application Ser. No. 61/927,268 filed Jan. 14, 2014 which all are incorporated herein by reference.

### FIELD OF INVENTION

This apparatus pertains generally to the field thermoelectric devices, and more particularly to thermoelectric devices for generating electrical current.

### BACKGROUND OF THE INVENTION

The thermoelectric effect (TE) is the direct conversion of temperature differences to electric voltage and vice versa. A thermoelectric device creates a voltage when it is supplied with different temperatures on each side thereof. Conversely, when a voltage is applied to the device, it creates a temperature difference. This effect can be used, for example, to generate electricity, measure temperature, and heat or cool objects.

The conversion of energy from thermal state to electrical state (the thermoelectric phenomenon) has been described in view of Seebeck effect, the Peltier effect and the Thomson effect. The Thomson effect occurs in a conductor when the ends of that conductor are at different temperatures and an electric current is flowing, generating a heating that is different than I.sup.2R heating, the difference being dependent on the magnitude and direction of the current, the temperature, and on the material. The Peltier effect describes the isothermal heat exchange that takes place at the junction of two different materials when an electrical current flows between them. The rate of development of heat is greater or less than that of Joule or I²R heating, the difference depending upon the direction and magnitude of the electric current, on the temperature, and on the two materials forming the junction. The Seebeck effect can be viewed as the sum of the Peltier and Thomson effects around a circuit loop.

The Peltier effect is caused by the fact that the electron's average energy varies from material to material. Thus, when a charged carrier such as an electron or a hole crosses from one material to another, the charged carrier compensates for the energy difference by exchanging heat with the surrounding lattice. The amount of heat exchanged for a given current I across a junction is determined by the Peltier coefficient. The Peltier coefficient is negative if heat is transported by the electrons and it is positive if heat is transported by holes.

Thus, when a semiconductor material is placed between a heat source and a heat sink, a favorable current flow through the semiconductor causes the heat to be extracted from the heat source and deposited on the heat sink. Applying these principles, conventional systems have been devised to provide solid state cooling, typically for electronic devices. However, conventional systems and thermoelectric modules have been inefficient in their capacity to conduct heat.

Alluding to the above, in the conventional thermoelectric module, two dissimilar elements with a P-type and an N-type conductivity are interconnected by commutating copper plates and enclosed between two flat ceramic plates. The ceramic plates are commonly formed of aluminum oxide or aluminum nitride. The heat is delivered to one end and removed from the other. In the thermoelectric modules, a thermal current is interrupted by an insulating layer of considerable thickness (ceramic plates based on aluminum oxide or aluminum nitride with anisotropic thermal conductivity). The thermal conductivity of the layer is significantly lower than electricity conductors. Thus, the thermal barrier created on the insulation layer prevents the seamless passage of heat through the thermoelectric semiconductor. Moreover, this layer is in contact with the adjacent surfaces, which also causes the loss of heat conductivity at the spots of the contacts.

Generally, thermoelectric modules may include a contact between a bus-bar and the pellets by soldering using low active rosin fluxes with minimum ion component concentrations for enhanced corrosion resistance of modules. This design however has serious complications. The soldered contact is a rigid mechanical connection. Not only does it position pellets, but it also serves as a thermoelectric conductor between a bus-bar and the pellets, and provides the structural strength of the module as a whole unit. Since the modern soldered modules operate at a significant temperature difference between their working surfaces, especially for cyclic applications, they are a subject of a thermal stress, especially at the periphery of the module. This reduces the allowable operating temperature difference, accelerates the aging process of the module (the damage and cracking of pellets) and limits the size of both the pellets and the module as a whole unit.

The prior art is replete with various thermoelectric modules used in various thermoelectric applications taught by U.S. Pat. No. 5,409,547 to Watanabe et al., U.S. Pat. No. 6,034,317 to Watanabe et al., U.S. Pat. No. 6,038,865 to Watanabe et al., U.S. Pat. No. 7,687,705 to Ila, and U.S. Pat. No. 7,816,601 to Carver. Some of the prior art thermoelectric modules contain the following pellets: bismuth telluride (Bi2Te3) crystals (pellets) of the P- and N-types. The dimension of the crystals: cross section from 0.35×0.35 mm to 2.4×2.4 mm, height 0.3÷5 mm, bismuth telluride (Bi2Te3) crystals (pellets) of the P- and N-type of conductivity with metal coating for thermoelectric cooling modules. The dimension of the crystals (length, width and height)—1.4×1.4×1.6 mm, bismuth telluride (Bi2Te3) crystals (pellets) of the P- and N-type conductivity for thermoelectric generator modules. The dimension of the crystals: the cross section of 5×5 mm, and bismuth telluride (Bi2Te3) crystals (pellets) of the P- and N-types. The dimension of the crystals: the cross-section from 0.8×0.8 mm to 2.5×2.5 mm.

These small pellets that are used in the modern thermoelectric modules can be mass-produced by sawing washers, derived from slabs. Due to a specific rectangular shape of the pellets and considerable width of a cut, a significant part of the thermoelectric material ends up in waste. Based on the analysis of the design, technological features and operating conditions of thermoelectric modules, the pellets are the “weakest” link in the module design due to the structural properties of thermoelectric materials based on bismuth telluride (Bi2Te3), as well as compression and tension forces applied to the pellets.

Analysis of common thermoelectric materials indicates that the materials have high structural heterogeneity based on differences in thickness and length of the grains. These differences are also observed between various areas of sample plates. There is a difference in the crystallographic orientation of grains, which can be noticed in the macro volumes, as well as the presence of the fragmentation of grains, and possibly pores between fragments. This, in turn, explains a significant spread of the mechanical characteristics of semiconductor pellets. The structural heterogeneity of the thermoelectric material and the spread of mechanical characteristics of the pellets negatively affect the operating stability and physical and mechanical properties of the pellets. As a result, the reliability of the thermoelectric module suffers significantly.

Various prior art thermoelectric devices, both thermoelectric generators and heat pumps, currently exist. A typical thermoelectric generator includes at least one thermoelectric module whose hot side is heated up by a liquid and thermoelectric conductors cooled down by a gaseous medium.

There is therefore a need in the art for an improved thermoelectric device that solves the deficiencies of the prior art. There is a need in the art for a thermoelectric device that is able to operate at lower temperature differentials and includes a simple and reliable structure. There is a need in the art for a thermoelectric device that has a high conversion efficiency in comparison to current prior art designs.

### SUMMARY OF THE INVENTION

In one aspect there is disclosed a thermoelectric device that includes at least one first heat exchange member. The first heat exchange member includes a conductive body having top and bottom surfaces joined by side surfaces. The top and bottom surfaces include a thin film of active material deposited thereon. The active material includes one of P-type and N-type thermoelectric materials positioned oppositely on the top and bottom surfaces. The thin film of active material includes an anti-diffusion coating deposited thereon. The anti-diffusion coating includes a joining layer deposited thereon. The conductive body of the first heat exchange member includes heat transfer passages formed therein receiving a heat transfer liquid. At least one second heat exchange member includes a conductive body having top and bottom surfaces joined by side surfaces. The top and bottom surfaces including a joining layer deposited thereon. The conductive body of the second member includes heat transfer surfaces formed therein receiving a heat transfer medium. The first and second heat exchange members are connected to each other at the joining layer and a temperature differential is created between the first and second heat exchange members.

In another aspect there is disclosed a thermoelectric device that includes a plurality of first heat exchange members including a conductive body having top and bottom surfaces joined by side surfaces. The top and bottom surfaces include a thin film of active material deposited thereon. The active material including one of P-type and N-type thermoelectric materials positioned oppositely on the top and bottom surfaces. The thin film of active material includes an anti-diffusion coating deposited thereon. The anti-diffusion coating includes a joining layer deposited thereon. The conductive body of the first member includes heat transfer passages formed therein receiving a heat transfer liquid. A plurality of second heat exchange members includes a conductive body having top and bottom surfaces joined by side surfaces. The top and bottom surfaces include a joining layer deposited thereon. The conductive body of the second member including heat transfer surfaces formed therein receiving a heat transfer medium. The first and second heat exchange members are connected to each other at the joining layer. The plurality of first and second conductive members are joined in a column and the active layers have alternating N and P type materials defining an electric circuit wherein a temperature differential is created between the first and second heat exchange members.

In a further aspect there is disclosed a thermoelectric device that includes a plurality of first heat exchange members including a conductive body having top and bottom surfaces joined by side surfaces. The top and bottom surfaces including a thin film of active material deposited thereon. The active material including one of P-type and N-type thermoelectric materials positioned oppositely on the top and bottom surfaces. The thin film of active material including an anti-diffusion coating deposited thereon. The anti-diffusion coating including a joining layer deposited thereon. The conductive body of the first member including heat transfer passages formed therein receiving a heat transfer liquid. A plurality of second heat exchange members includes a conductive body having top and bottom surfaces joined by side surfaces. The top and bottom surfaces including a joining layer deposited thereon. The conductive body of the second member including heat transfer surfaces formed therein receiving a heat transfer medium. The first and second heat exchange members are connected to each other at the joining layer and the plurality of first and second conductive members are joined in a column wherein the active layers have alternating N and P type materials defining an electric circuit. Top, bottom and side frame members may be electrically isolated from the first and second conductive members and house the column of first and second conductive members. At least one of hot and cold manifolds is attached to the side frame members for supplying the heat transfer liquid. Connection rods that are insulated or formed on insulating materials are attached to the top and bottom frame members. The connecting rods are received in connection bores formed in the first and second conductive members. A temperature differential is created between the first and second heat exchange members.

### BRIEF DESCRIPTION OF THE DRAWINGS

FIG. 1A-C includes a perspective view and sectional views of one embodiment of a thermoelectric device having a liquid to liquid heat exchange;

FIG. 2A-B includes an exploded perspective view of the embodiment of FIG. 1;

FIG. 3 includes a schematic view of the embodiment of FIG. 1 detailing the heat flow and electric current flow of the thermoelectric device;

FIG. 4 is an alternative cubic array of the embodiment of FIG. 1;

FIG. 5A-D includes an exploded perspective view, side and front views and sectional views of another embodiment of a thermoelectric device having liquid to air heat exchange;

FIG. 6A-B includes an exploded perspective view, and views of the first and second heat exchange members of another embodiment of a thermoelectric device having liquid to infra-red heat exchange;

FIG. 7 is a plot of the heat flow and power for the apparatus of the present invention in comparison to prior art devices;

FIG. 8 is a depiction of prior art devices.

### DETAILED DESCRIPTION OF THE INVENTION

Referring to the Figures, there is disclosed a thermoelectric device 10 that includes at least one first heat exchange member 12. The first heat exchange member 12 includes a conductive body 14 having top and bottom surfaces 16, 18 joined by side surfaces 20. In one aspect, the first heat exchange member may be formed of a conductive metal that allows for both electrical and heat conduction. In one aspect the first heat exchange member may be formed of aluminum or an aluminum alloy. Other suitable metals include Nickel alloys, Tin, and bronze and other metals that have high electrical and thermal conductivity.

The top and bottom surfaces 16, 18 include a thin film of active material 24 deposited thereon. The active material 24 includes one of P-type and N-type thermoelectric materials positioned oppositely on the top and bottom surfaces 16, 18. The active material 24 may have a thickness of from 4-8 microns or may be thicker based on the application method utilized. In one aspect, the active material 24 may be a polycrystalline thermoelectric material having a crystal structure that is oriented along a flow of heat in the first heat exchange member 12. The active material 24 may be applied by a vacuum deposition process that applies the active material 24 directly to the conductive body 14 of the first heat exchange member 12. The active material 24 may be formed of bismuth telluride or other suitable thermoelectric materials. The N type material may include selenium doped bismuth telluride and the P type material may include antimony doped bismuth telluride.

The thin film of active material 24 includes an anti-diffusion coating 26 deposited thereon. The anti-diffusion coating 26 prevents degradation of the active material 24. In one aspect, the anti-diffusion coating 26 may be formed of aluminum, gold or nickel and have a thickness of from 2-4 microns. The anti-diffusion coating 26 may be applied by a vacuum deposition process. Other suitable metals may be utilized that do not include highly mobile and active ions. For example, the metals copper or lead include mobile ions and may not be suitable for the anti-diffusion layer. Other mobile materials may also present problems.

The anti-diffusion coating 26 includes a joining layer 28 deposited thereon. The joining layer 28 may include a solder 30 and flux 32 for connecting the various components. The joining layer 28 may be applied by a vacuum deposition process. Suitable solder materials include a tin solder and appropriate flux material to insure even flow and bonding when the various components are joined. The joining layer 28 may have a thickness of from 2-4 microns. The joining layer may also be thicker based on the method utilized to deposit the material.

The conductive body 14 of the first heat exchange member 12 includes heat transfer passages 34 formed therein receiving a heat transfer liquid. The passages 34 allow for transfer of either a hot or cold heat exchange liquid within the first heat exchange member 12 to create a desired temperature differential. In one aspect, the passages 34 include an inlet 13 and outlet formed 15 formed in the conductive body 14 with transfer passages 17 connecting the inlet 13 and outlet 15 to allow for the transfer of thermal energy to the heat exchange liquid.

At least one second heat exchange member 36 includes a conductive body 38 having top and bottom surfaces 40, 42 joined by side surfaces 44. The top and bottom surfaces 40, 42 including a joining layer 28 deposited thereon. The joining layer 28 may include similar materials as described above with respect to the first heat exchange member 12.

The conductive body 38 of the second member 36 includes heat transfer surfaces 46 formed therein receiving a heat transfer medium. Various embodiments of the second heat exchange member 36 will be described in detail below. The first and second heat exchange members 12, 36 are connected to each other at the joining layer 28 and a temperature differential is created between the first and second heat exchange members 12, 36.

Direct contact of the active material 24 with the second heat exchange member 26 with limited thermal barriers, will increase thermal flow through each active layer 24. This arrangement provides a thermoelectric device 10 that can operate efficiently even when small difference in temperatures exists such as from 5 degrees Centigrade and higher between hot and cold active materials 24. The first and second heat exchange members 12, 36 are aligned in a row presenting a path inside each of the first and second heat exchange members 12, 36 to exchange heat.

An advantage of the present apparatus is to provide an improved thermoelectric device or Power Radiator including a plurality of first and second heat exchange members 12, 36 adjacent to one another with a plurality of active layers 24 sandwiched between the first and second heat exchange members 12, 36. Another advantage of the present apparatus is to provide an improved thermoelectric device presenting a design of multiple thermoelectric conductors interconnected with one another unlike a unitary thermoelectric housing of prior art devices, thereby increasing efficiency by transferring the heat through the thermoelectric semiconductor avoiding any significant thermal barriers.

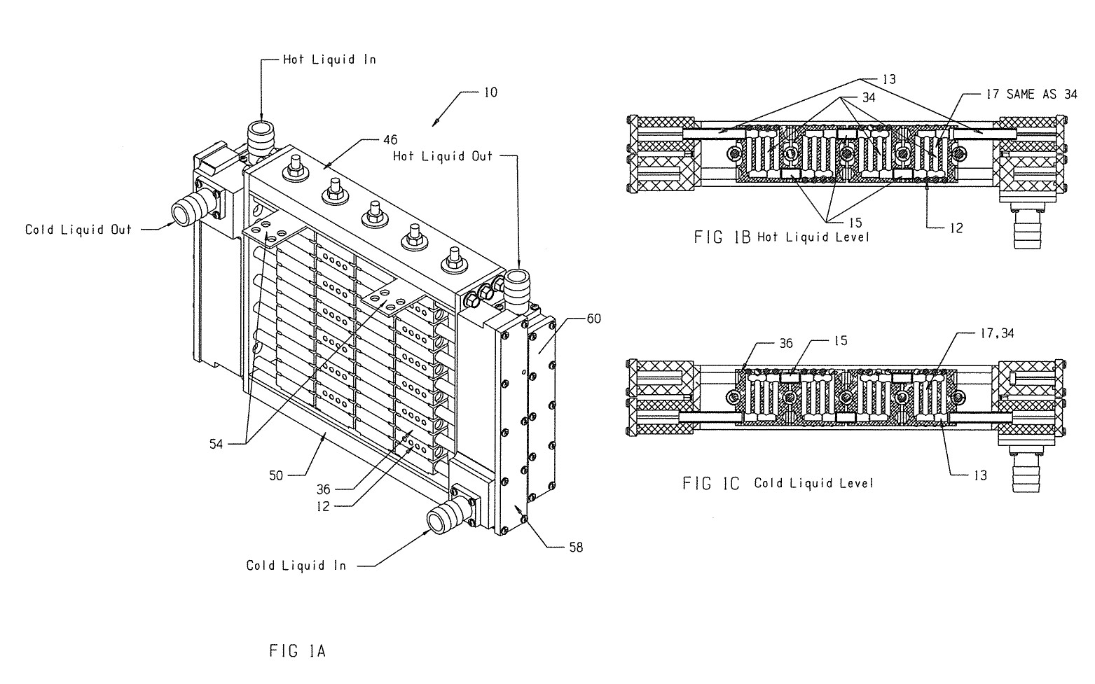

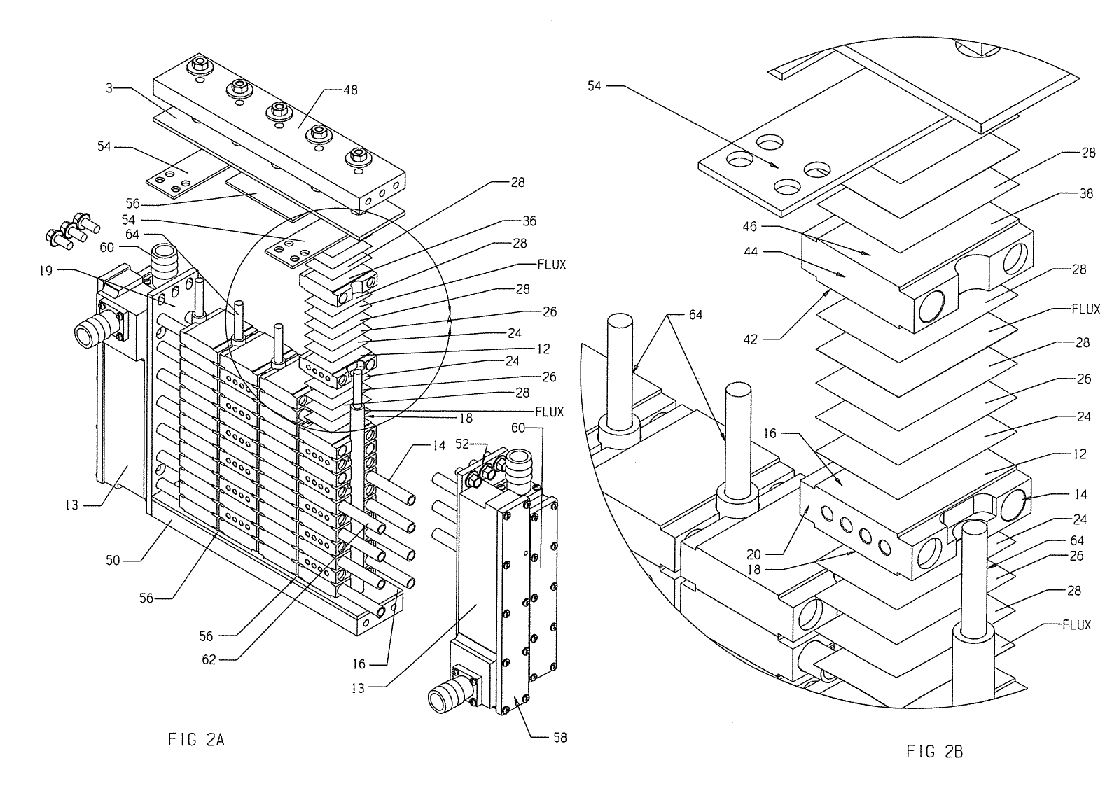

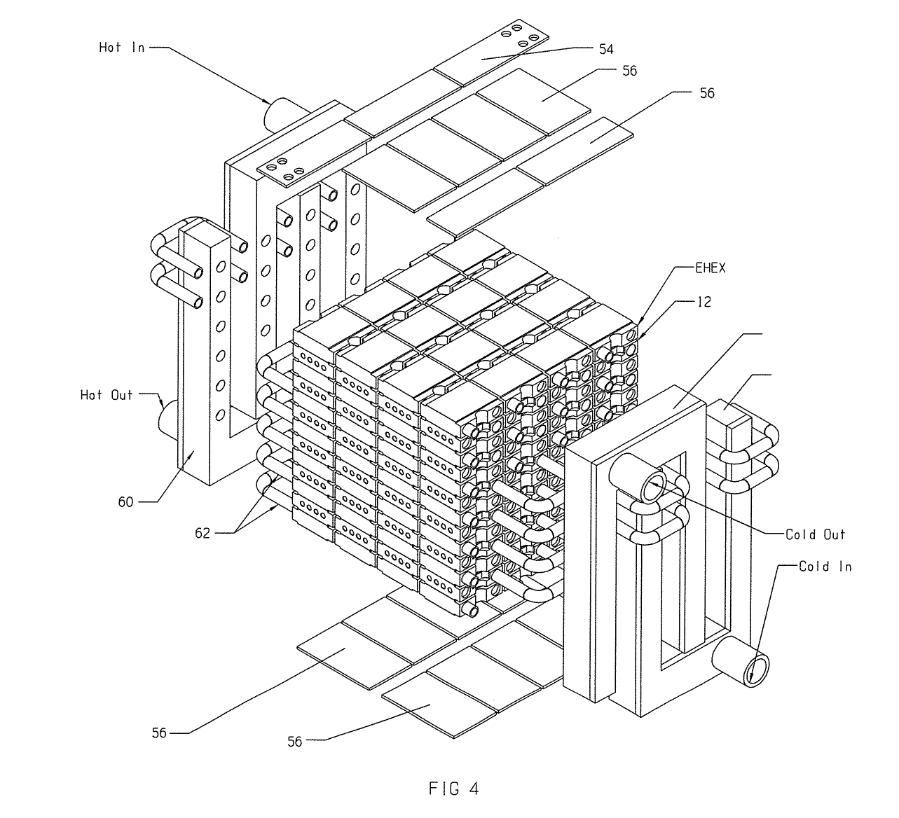

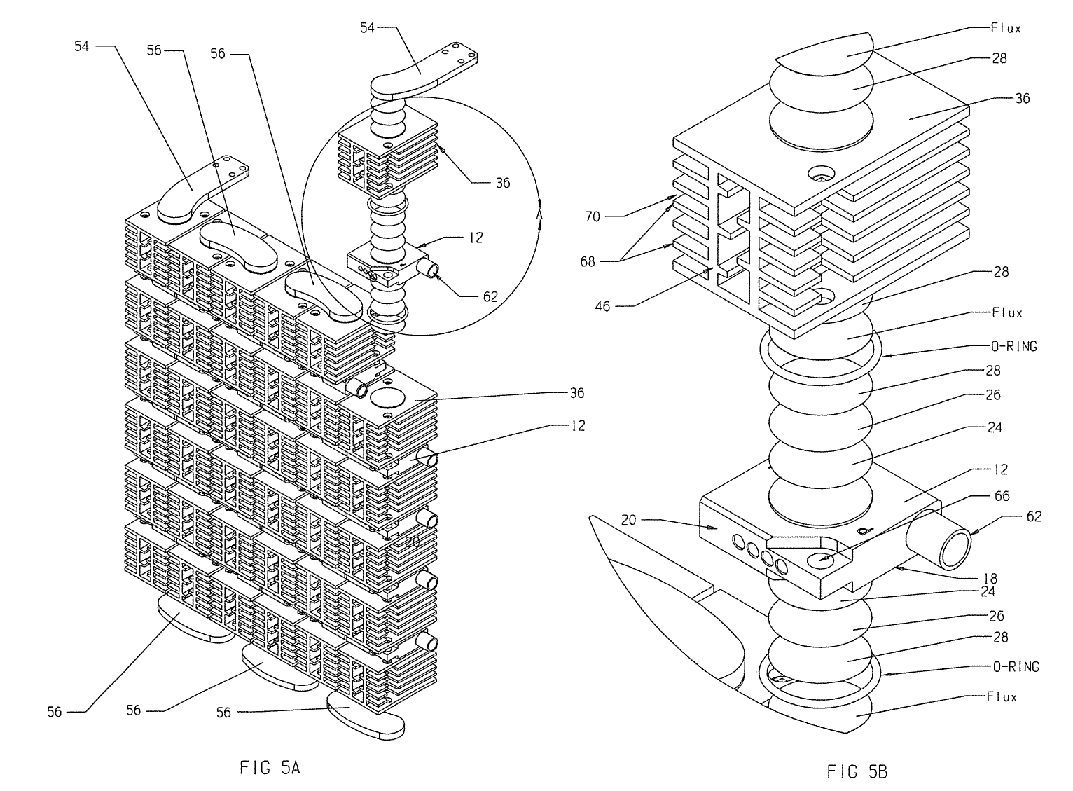

Referring to FIGS. 1-4, there is shown an embodiment of a thermoelectric device 10. In the depicted embodiment, a plurality of first and second heat exchange members 12, 36 are joined in a column where the active materials 24 have alternating N and P type materials applied on the top and bottom surfaces 16, 18 of the first heat exchange members 12 defining an electric circuit. The conductive body 14 of the first heat exchange member 12 includes heat transfer passages 34 formed therein receiving a heat transfer liquid. The passages 34 allow for transfer of either a hot or cold heat exchange liquid within the first heat exchange member 12 to create a desired temperature differential. In one aspect, the passages 34 include an inlet 13 and outlet formed 15 formed in the conductive body 14 with transfer passages 17 connecting the inlet 13 and outlet 15 to allow for the transfer of thermal energy to the heat exchange liquid. The depicted embodiment includes a plurality of columns of first and second heat exchange members 12. 36 that define an array. Various numbers of columns may be utilized based on the application. In the depicted embodiment of FIGS. 1-3 there are provided four columns arranged in a rectangular pattern. Alternatively, the columns may be arranged in a square configuration as shown in FIG. 4 with 16 columns shown. Various numbers of columns may be arranged in differing patterns. In one aspect, adjacent columns may have a reverse sequence of N and P type active materials 24 that are connected in series.

The second heat exchange member 36 has the same structure as the first heat exchange member 12 without the application of the active material 24 and anti-diffusion layer 26. The depicted embodiment defines a liquid to liquid heat exchanger.

The columns of first and second heat exchange members 12, 36 may be received in a housing 46 that includes top 48, bottom 50 and side 52 frame members housing the column of first and second conductive members 12, 36. The thermoelectric device 10 further includes external contacts 54 and a connecting bridge 56 for passing electrical current. At least one of hot and cold manifolds 58, 60 are attached to the side frame members 52 for supplying the heat transfer liquid, with two being shown in the depicted embodiment of FIGS. 1-4. The hot and cold manifolds 58, 60 are fluidly coupled to the first and second heat exchange members 12, 36 by appropriate tubes 62. The hot and cold manifolds 58, 60 may be connected to either of the first and second heat exchange members 12, 36. In the depicted embodiment of FIGS. 1-4, the hot manifold 58 is coupled to the first heat exchange member 12 and the cold manifold 60 is coupled to the second heat exchange member 36.

The thermoelectric device 10 may include connection rods 64 attached to the top and bottom frame members 48, 50. The connecting rods 64 may be formed of electrically insulating material or have an insulated coating and are received in connection bores 66 formed in the first and second heat exchange members 12, 36 to maintain a position of the first and second heat exchange members 12, 36.

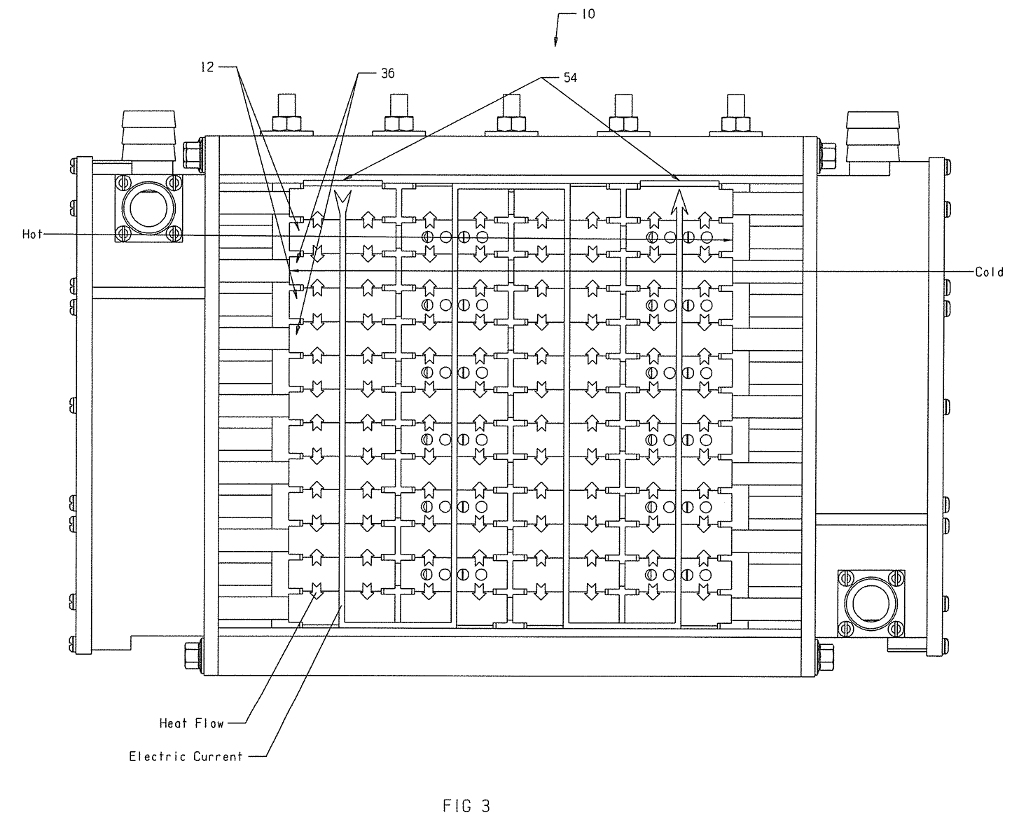

When assembled in groups, the first and second heat exchange members 12, 36 and the active layers 24 are connected in the successive circuit by electricity conductive bridges 56 and are aligned in such a way that the direction of electric current in the adjacent group are mutually opposite, as illustrated in FIG. 3. The heat transfer fluid of the hot and cold manifolds 58, 60 moves across the first and second heat exchange members 12, 36 as indicated by the arrows. Thermal energy is moved between the first and second heat exchange members 12, 36 as indicated by the arrows to create the temperature differential.

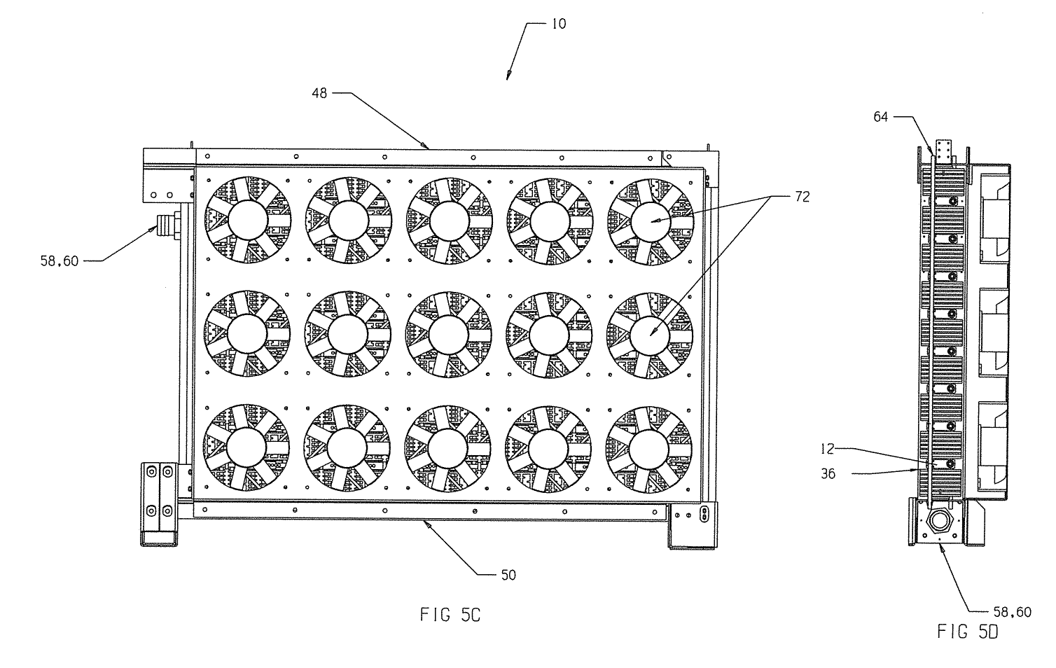

Referring to FIG. 5, there is shown another embodiment of a thermoelectric device 10. The first heat exchange member 12 is the same as described with respect to the embodiment of FIGS. 1-3. As described above, the active material 24 may be a Polycrystalline Thin Film applied directly to the first heat exchange member 12. The active material 24 may be applied in various patterns, for example cross-strips pattern, circular, square, rectangular or other patterns.

At least one second heat exchange member 36 includes a conductive body 38 having top and bottom surfaces 40, 42 joined by side surfaces 44. The top and bottom surfaces 40, 42 including a joining layer 28 deposited thereon. The joining layer 28 may include similar materials as described above with respect to the first heat exchange member 12.

The conductive body 38 of the second member 36 includes heat transfer surfaces 46 formed therein receiving a heat transfer medium. The first and second heat exchange members 12, 36 are connected to each other at the joining layer 28 and a temperature differential is created between the first and second heat exchange members 12, 36.

The second heat exchange member 36 includes a plurality of separated walls 68 joined by the top and bottom surfaces 40, 42. The separated walls 68 define air passages 70 there between. In one aspect, the second heat exchange members 36 are associated with a fan or other device 72 to move air across the heat exchange member. In one aspect, the second heat exchange member 36 presents an extruded body with two parallel top and bottom surfaces 40, 42, which are positioned perpendicularly to the direction of the airflow.

The depicted embodiment of FIG. 5 defines a liquid to air heat exchanger or Power Radiator. The depicted embodiment includes a plurality of columns of first and second heat exchange members 12, 36 that define an array. Various numbers of columns may be utilized based on the application. In the depicted embodiment of FIG. 5 there are provided 6 columns arranged in a rectangular pattern. Various numbers of columns may be arranged in differing patterns. In one aspect, adjacent columns may have a reverse sequence of N and P type active materials 24 that are connected in series. Either of the cold or hot heat exchange fluid may be provided in either of the first or second heat exchange members 12, 36. The cold or hot manifold 58, 60 may supply a desired fluid to the first heat exchange member 12 and the second heat exchange member 36 may receive a hot or cold gas such as air or steam.

The columns of first and second heat exchange members 12, 36 may be received in a housing 46 that includes top 48, bottom 50 and side 52 frame members housing the column of first and second heat exchange members 12, 36. The thermoelectric device further includes external contacts 54 and a connecting bridge 56 for passing electrical current. At least one of hot and cold manifolds 58, 60 is attached to the side frame members 52 for supplying the heat transfer liquid. The hot or cold manifolds 58, 60 are fluidly coupled to the first heat exchange member 12 by appropriate tubes 62 that are electrically insulated.

The thermoelectric device 10 may include connection rods 64 attached to the top and bottom frame members 48, 50. The connecting rods 64 may be formed of insulating material or have an insulated coating and are received in connection bores 66 formed in the first and second heat exchange members 12, 36 to maintain a position of the first and second heat exchange members 12, 36.

In one aspect, the second heat exchange members 36 are positioned to receive heat by direct heat exchange with a hot heat carrier such as air or gas and transfer heat to the active layers 24. The first heat exchange members 12 are configured to receive heat from the active layers 24 then pass it through by direct heat exchange with a cold heat carrier. The hot heat carrier can be presented by a vapor-gaseous medium. The cold heat carrier can be presented as a cooled liquid. As specified above, the hot and cold transfer may be reversed.

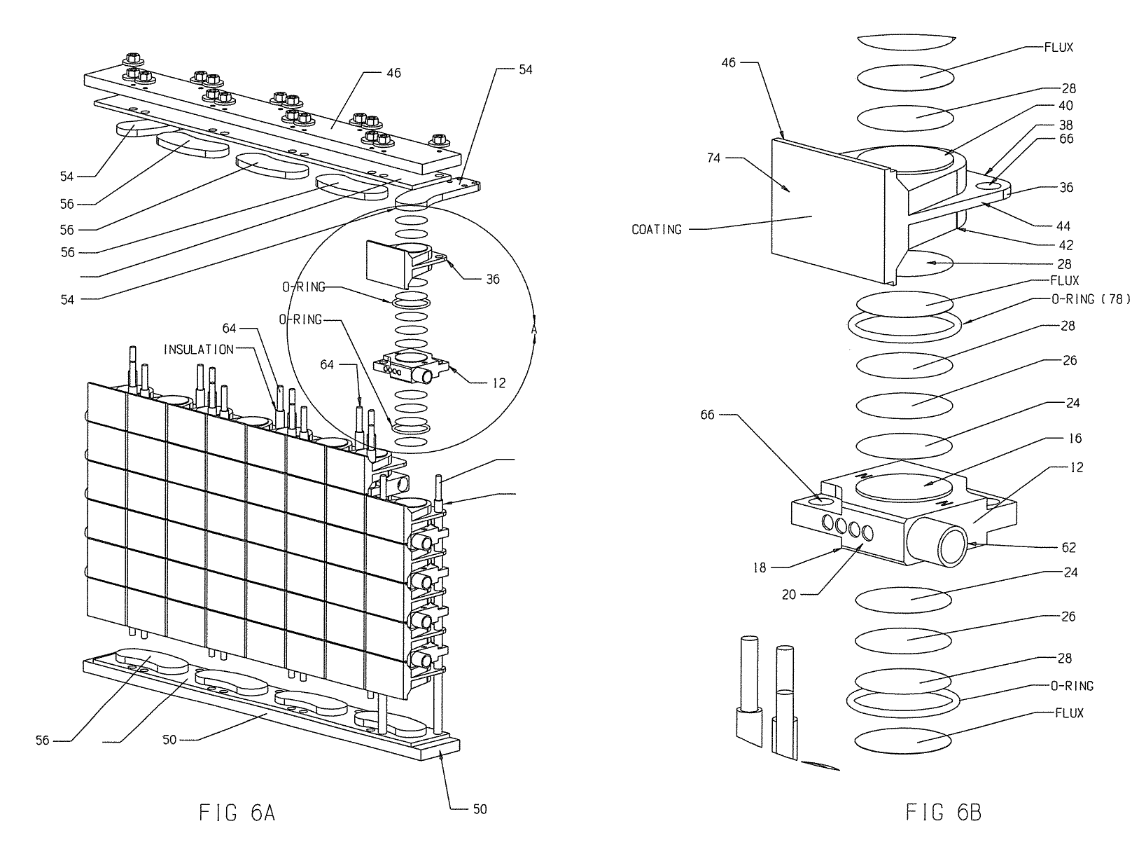

Referring to FIG. 6, there is shown another embodiment of a thermoelectric device 10. The first heat exchange member 12 is the same as described with respect to the embodiment of FIGS. 1-3. As described above, the active material 24 may be a Polycrystalline Thin Film applied directly to the first heat exchange member. The active material 24 may be applied in various patterns, for example cross-strips pattern, circular, square, rectangular or other patterns.

At least one second heat exchange member 36 includes a conductive body 38 having top and bottom surfaces 40, 42 joined by side surfaces 44. The top and bottom surfaces 40, 42 including a joining layer 28 deposited thereon. The joining layer 28 may include similar materials as described above with respect to the first heat exchange member 12.

The conductive body 38 of the second member 36 includes heat transfer surfaces 46 formed therein receiving a heat transfer medium. The first and second heat exchange members 12, 36 are connected to each other at the joining layer 28 and a temperature differential is created between the first and second heat exchange members 12, 36.

The second heat exchange member 36 includes an infrared conducting side surface 74. The side surface 74 may include a coating formed thereon that improves absorption of infrared radiation. The depicted embodiment of FIG. 6 defines a liquid to infra-red heat exchanger. The depicted embodiment includes a plurality of columns of first and second heat exchange members 12, 36 that define an array. Various numbers of columns may be utilized based on the application. In the depicted embodiment of FIG. 6 there are provided 8 columns arranged in a rectangular pattern. Various numbers of columns may be arranged in differing patterns. In one aspect, adjacent columns may have a reverse sequence of N and P type active materials that are connected in series.

In the depicted embodiment, the first heat exchange member 12 may be coupled to a cold manifold 60 and the second heat exchange member 36 provides a thermal heat from the infrared radiation.

The columns of first and second heat exchange members 12, 36 may be received in a housing 46 that includes top 48, bottom 50 and side 52 frame members housing the column of first and second heat exchange members 12, 36. The thermoelectric device 10 further includes external contacts 54 and a connecting bridge 56 for passing electrical current. At least one of hot and cold manifolds 58, 60 is attached to the side frame members 52 for supplying the heat transfer liquid. The hot or cold manifolds 58, 60 are fluidly coupled to the first heat exchange member 12 by appropriate tubes 62 that are electrically insulated.

The connecting rods 64 may be formed of insulating material or have an insulated coating and are received in connection bores 66 formed in the first and second heat exchange members 12, 36 to maintain a position of the first and second heat exchange members 12, 36.

The active layers 24 may be formed in a shape of a washer. The active layer 24 may also include a non-circular configuration. The active layers 24 may be surrounded by a resilient element such as, for example an O-ring 78, to protect the active layers 24. The protective element 78, may be positioned in depressions or grooves defined in the top and bottom surfaces of the heat exchange members 12, 36. The second heat exchange member 36 may be formed from any type of thermal and electro conductive material, such as Nickel alloys, bronze and tin and other materials.

### EXAMPLES

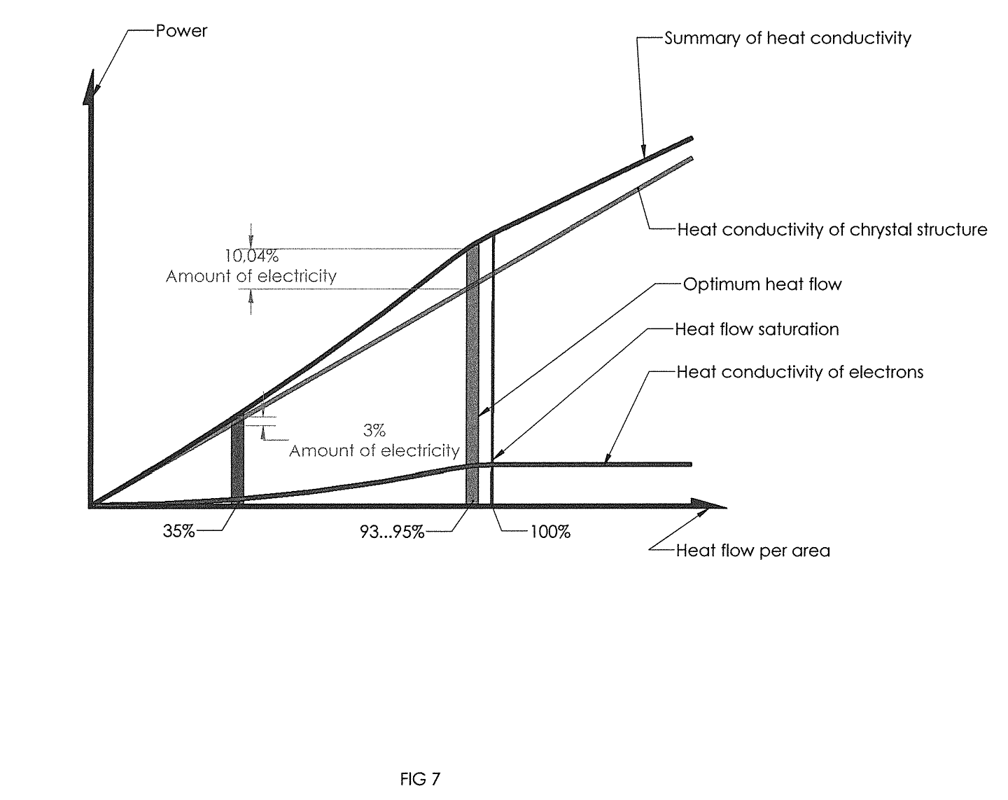

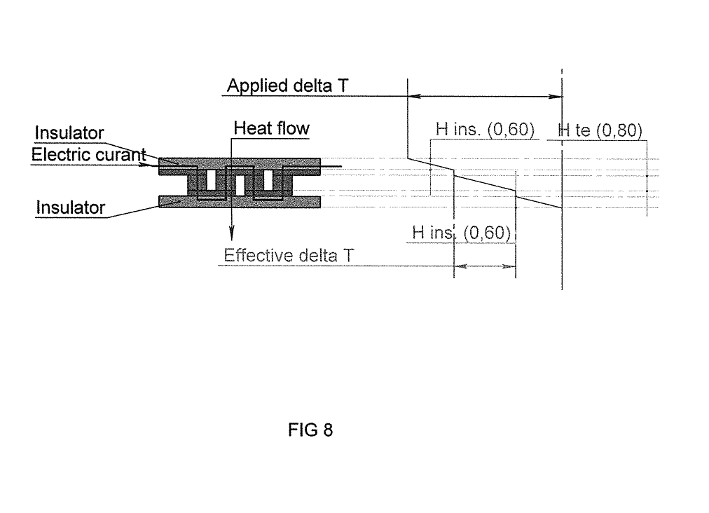

Referring to FIG. 7, there is shown a plot of the heat flow and power for the device of the present invention in comparison to prior art devices such as that shown in FIG. 8. The plot was generated from data gathered from an experiment targeted on detection of the portion of electrons in the samples of the thermoelectric material. The sample: polycrystalline thin film of thermoelectric material (bismuth telluride) having a thickness of 6 micron with a surface area of 3 square centimeters was applied directly on a plate of aluminum alloy (6 mm thick) and coated with an anti-diffusion layer aluminum 2-4 microns thick and also joined, by soldering, with another piece of 6 mm thick aluminum alloy plate.

An electric heater was utilized to provide measurable precise temperatures. The flow of the hot air was applied vertically upwards. Transmitted power was calculated by measuring the temperature gradient along the thickness in the upper plate. Heat dissipation performed by the liquid (water) with a thermostat with circulating media and power measurement of a refrigerator. The measurement results are shown in FIG. 7 in conventional values and %.

With a continuous increase of the incoming heat flow by increasing the temperature to the sample a temperature difference, and a conducted thermal power of the sample was measured. The plot of the Line of crystal thermal conductivity of the crystal was obtained by the electrical connection of top and bottom plates. The connection was made by thick (15 square mm cross section) copper cable to minimize electrical resistance. The cable provided for measuring the electro current generation of one TE layer, measuring the power of this generation in the condition of “short circuit”. When measuring with a disconnected cable, a curve was obtained for the total thermal conductivity. The difference between the measured readings of thermal conductivity of the sample and the total thermal conductivity was calculated and plotted.

In Bismuth Telluride (Bi2Te3) and other semiconductors of the same type, the Seebeck effect starts the electrical current in the form of the heat flow through itself, which is the realization of the electronic structure of the thermal conductivity of the semi-conductor. The presence of a high electro and thermal conductivity such as in metals such as copper, aluminum provide materials for the heat exchange members.

In general the thermal conductivity and electro conductivity are changed synchronously—decrease and increase proportionally, that is the thermal conductivity has an influence on the electro conductivity due to the charge carriers or electrons. For this reason, the best heat conductors among electro insulating materials have heat conductivity 20-30 times less than good electrical conductors as they do not have free charge carriers.

For effective implementation of thermoelectric devices it is desirable to combine high heat flux with the comparatively low content of mobile charge carriers-electrons or holes in the substance, but with low specific resistance of electric current. The substance may have a crystalline structure oriented along the flow of heat and along the electro driving force creating a smaller number of obstacles for the charge carriers. To maximize the heat transfer of available mobile charge carriers, the heat flow may have a high intensity so that the remaining “extra” carriers will not run against the electro-motive force and neutralize the movement of charge carriers. In the depicted FIG. 7, this property is indicated as the saturation.

In the examples bismuth telluride materials were utilized to build devices for the direct conversion of thermal energy into electrical energy based on Bi2Te3 with additives for organization N type and P-type conductivity.

As shown in FIG. 7, optimum may be considered 93 . . . 95% of the heat flow saturation. P-type (BiSb)2Te3, doped by antimony may be provided as a pressed powder alloy obtained by heat treat process from a liquid state (SGS) includes the following properties: α=160 MκB/K; ρ=6×10⁻⁴ OM·cM; [symbol] =(1.40÷1.45)×10⁻²BT/cM·K; Z=(2.96÷3.0)×10⁻³ K⁻¹

N-type (BiSe)₂Te₃, doped by selenium may be provided as a pressed powder alloy obtained by heat treat process from a liquid state (SGS) includes the following properties: α=174 MκB/K; ρ=12×10⁻⁴ OM·cM; [symbol] =(1.15÷1.2)×10⁻²BT/cM·K; Z=(2.1÷2.19)×10⁻³ K⁻¹

Optimal heat flow for this thermoelectric material was around 20 W/cm2, which can be achieved for a temperature difference of 5 degrees Centigrade with a layer thickness of thermoelectric material of 6 microns.

This property indicates that to build devices for the direct conversion of thermal energy into electrical energy with maximum efficiency the following characteristics may be relevant: Apply thermoelectric material in the form of thin films with thickness of 4-8 mm and achieve heat flow through these films at the level of 93 . . . 95% of the Heat flow saturation for specific thermoelectric material by selecting the required area of the film.

The deposition of Poly crystalline thin films directly on electro and heat-conducting bases made from aluminum alloys such as type 6061, etc. and the formation of anti-diffusion and joining layers using vacuum-plasma deposition processes allows for achievement of the desired properties. The thermoelectric devices of the present invention allow for achieving a conversion of thermal energy into electrical energy on the order of 10% which is much higher than conventional prior art thermoelectric devices.

In one aspect, there is the availability to vary the number of active layers 24 depending on the working temperature differences, physical state, temperature and properties of matter, the source of heat, physical state, temperature and properties of the substances.

Referring to FIG. 8, the prior art design of the TE module is the standard for worldwide manufacturers and is produced in large quantities. The design typically has between 100 to 300 pairs TE transitions of N- and P-types. Along the direction of the heat flow are two layers of insulator (this is necessary for the maintaining proper flow of electric current). The prior art devices are made of thermally conductive materials such as ceramics. As a practice, the thickness is of about 0.6 mm. As we previously mentioned, in the best case the conductivity of these insulators reaches 10 . . . 20 W/MMK, which is 20 times less, than, for example, copper and only slightly exceeds the thermal conductivity of thermoelectric material. The figure conditionally shows the gradient applied to such a thermoelectric module. Because of the low thermal conductivity of insulators the temperature difference applied actually on the thermoelectric element (Effective T) decreases relative to the applied as a proportion of the thickness: Hte/2Hins. This means that there is no reason to decrease the thickness of thermoelectric elements in the module. As the effective temperature difference is close to zero, and there will be no significant Seebeck Effect.

Regardless of the reduction of the thickness of thermoelectric elements of the prior art they still remain insulators so that there is no way to reach the heat flow approaching saturation for temperature differences of less than 100° C. In this state, the heat flux is around 30-35% of the saturation point.

FIG. 7 shows that heat flux of about 35% from saturation provides efficiency from the thermo electric conversion of around 3% versus 10% in the Optimum area as provided by the present invention. The thermoelectric devices of the present invention provides a fundamentally different approach to the design of a thermoelectric converter of thermal energy into electrical energy capable of producing up to 10% efficiency of the conversion of thermal with a temperature difference of 5° C. and higher.

The thermoelectric device of the present invention may be utilized as an electric generator to regenerate wasted heat energy that effectively generates electricity with small working difference of the temperature due to: an active layer of Polycrystalline Thin-Films of thermoelectric substance, like Bi2Te3. The devices of the present invention provides good heat exchange with minimal loss of heat to and from the active layers. The Modular structure of devices of the present invention allows the opportunity to build various devices for different applications, configurations, sizes and strength. The devices of the present invention may find use in power recovery in refrigeration, air conditioning devices and all types of heat pumps, power recovery in cooling radiators for wide range of structures including cars, ships, chemical and other heat treatment enterprises, recovery of residual heat of electro stations, creation of geothermal elect stations, and creation of highly effective heaters and solar collection stations for generating electricity.

While the apparatus has been described with reference to an exemplary embodiment, it will be understood by those skilled in the art that various changes may be made and equivalents may be substituted for elements thereof without departing from the scope of the apparatus. In addition, many modifications may be made to adapt a particular situation or material to the teachings of the apparatus without departing from the essential scope thereof. Therefore, it is intended that the apparatus not be limited to the particular embodiment disclosed as the best mode contemplated for carrying out this apparatus, but that the apparatus will include all embodiments falling within the scope of the appended claims.

1. A thermoelectric device comprising:
at least one first heat exchange member including a conductive body having top and bottom surfaces joined by side surfaces, said top and bottom surfaces including a thin film of active material deposited thereon, said active material including one of P-type and N-type thermoelectric materials positioned oppositely on said top and bottom surfaces, said thin film of active material including an anti-diffusion coating deposited thereon, said anti-diffusion coating including a joining layer deposited thereon, said conductive body of said first member including heat transfer passages formed therein receiving a heat transfer liquid;
at least one second heat exchange member including a conductive body having top and bottom surfaces joined by side surfaces, said top and bottom surfaces including a joining layer deposited thereon, said conductive body of said second member including heat transfer surfaces formed therein receiving a heat transfer medium;
wherein said first and second heat exchange members are connected to each other at the joining layer and wherein a temperature differential is created between the first and second heat exchange members.

2. The thermoelectric device of claim 1 wherein the heat transfer passages of the first heat exchange member includes an inlet and outlet formed in the conductive body joined by transfer passages.

3. The thermoelectric device of claim 1 wherein the active material has a thickness of from 4-8 microns and is vacuum deposited on the conductive body.

4. The thermoelectric device of claim 1 wherein the active material includes a polycrystalline thermoelectric material having the crystalline structure oriented along a flow of heat.

5. The thermoelectric device of claim 1 wherein the active material includes bismuth telluride.

6. The thermoelectric device of claim 1 wherein the bismuth telluride includes lead doped bismuth telluride forming P-type and wherein the bismuth telluride includes selenium doped bismuth telluride forming N-type materials.

7. The thermoelectric device of claim 1 wherein the anti-diffusion coating is formed of a material selected from the group consisting of: aluminum, gold, and nickel.

8. The thermoelectric device of claim 1 wherein the joining layer includes a solder formed of tin material and applied at a thickness of from 2-4 microns and flux.

9. The thermoelectric device of claim 1 wherein the thermoelectric device includes a plurality of first and second conductive members joined in a column and wherein the active layers have alternating N and P type materials defining an electric circuit.

10. The thermoelectric device of claim 9 including a plurality of columns of first and second conductive members defining an array.

11. The thermoelectric device of claim 10 wherein adjacent columns have a reverse sequence of N and P type thermoelectric materials and are connected in series.

12. The thermoelectric device of claim 10 wherein the plurality of columns of the array are connected in a rectangular or square pattern.

13. The thermoelectric device of claim 1 wherein the second heat exchange member includes a plurality of separated walls joined by the top and bottom surfaces, the separated walls defining air passages there between.

14. The thermoelectric device of claim 1 wherein the second heat exchange member includes an infrared conducting side surface.

15. The thermoelectric device of claim 9 wherein the device further includes external contacts and a connecting bridge for passing electrical current.

16. The thermoelectric device of claim 9 further including top, bottom and side frame members housing the column of first and second conductive members.

17. The thermoelectric device of claim 16 including at least one of hot and cold manifolds attached to the side frame members for supplying the heat transfer liquid.

18. The thermoelectric device of claim 16 including electrically insulated connection rods attached to the top and bottom frame members, the connecting rods received in connection bores formed in the first and second conductive members.

19. The thermoelectric device of claim 1 wherein the temperature differential is from 5 degrees Centigrade and higher.

20. The thermoelectric device of claim 1 wherein a converter efficiency of thermal energy into electrical energy is from 5% to 10%.

21. A thermoelectric device comprising:
a plurality of first heat exchange members including a conductive body having top and bottom surfaces joined by side surfaces, said top and bottom surfaces including a thin film of active material deposited thereon, said active material including one of P-type and N-type thermoelectric materials positioned oppositely on said top and bottom surfaces, said thin film of active material including an anti-diffusion coating deposited thereon, said anti-diffusion coating including a joining layer deposited thereon, said conductive body of said first member including heat transfer passages formed therein receiving a heat transfer liquid;
a plurality of second heat exchange members including a conductive body having top and bottom surfaces joined by side surfaces, said top and bottom surfaces including a joining layer deposited thereon, said conductive body of said second member including heat transfer surfaces formed therein receiving a heat transfer medium;
wherein said first and second heat exchange members are connected to each other at the joining layer and wherein the plurality of first and second conductive members are joined in a column and wherein the active layers have alternating N and P type materials defining an electric circuit wherein a temperature differential is created between the first and second heat exchange members.

22. The thermoelectric device of claim 21 wherein the second heat exchange member includes a plurality of separated walls joined by the top and bottom surfaces, the separated walls defining air passages there between, the first and second heat exchange members defining a liquid to air heat exchange device.

23. The thermoelectric device of claim 21 wherein the second heat exchange member includes a conductive body including heat transfer passages formed therein receiving a heat transfer liquid the first and second heat exchange members defining a liquid to liquid heat exchange device.

24. The thermoelectric device of claim 21 wherein the second heat exchange member includes an infrared conducting side surface, the first and second heat exchange members defining a liquid to solid heat exchange device.

25. A thermoelectric device comprising:
a plurality of first heat exchange members including a conductive body having top and bottom surfaces joined by side surfaces, said top and bottom surfaces including a thin film of active material deposited thereon, said active material including one of P-type and N-type thermoelectric materials positioned oppositely on said top and bottom surfaces, said thin film of active material including an anti-diffusion coating deposited thereon, said anti-diffusion coating including a joining layer deposited thereon, said conductive body of said first member including heat transfer passages formed therein receiving a heat transfer liquid;
a plurality of second heat exchange members including a conductive body having top and bottom surfaces joined by side surfaces, said top and bottom surfaces including a joining layer deposited thereon, said conductive body of said second member including heat transfer surfaces formed therein receiving a heat transfer medium;
wherein said first and second heat exchange members are connected to each other at the joining layer and wherein the plurality of first and second conductive members are joined in a column and wherein the active layers have alternating N and P type materials defining an electric circuit;
top, bottom and side frame members housing the column of first and second conductive members;
at least one of hot and cold manifolds attached to the side frame members for supplying the heat transfer liquid;
electrically insulated connection rods attached to the top and bottom frame members, the connecting rods received in connection bores formed in the first and second conductive members;
wherein a temperature differential is created between the first and second heat exchange members.
